(19) United States
(12) Patent Application Publication
(10) Pub. No.: US 2006/0131616 A1
(43) Pub. Date: Jun. 22, 2006

(54) Copperless flexible circuit

(76) Inventors: Douglas E. Devaney, Austin, TX (US); David C. Lueneburg, Austin, TX (US)

Correspondence Address: 3M INNOVATIVE PROPERTIES COMPANY, PO BOX 33427, ST. PAUL, MN, 55133-3427, US

(21) Appl. No.: 11/018,948

(22) Filed: Dec. 21, 2004

(51) Int. Cl. H01L 29/768; H01L 27/148

(52) U.S. Cl. 257/226

(57) ABSTRACT

This invention relates to a copperless flexible circuit; more particularly, a two-sided copperless flexible circuit.

### TECHNICAL FIELD

This invention relates to a copperless flexible circuit; more particularly, a two-sided copperless flexible circuit.

### BACKGROUND

Flexible circuits are useful in many electrical and electronic applications. For example, they can be used in integrated circuits, semiconductors, connectors, and medical diagnostic devices. Most flexible circuits have copper in their conductive layers. When used in medical diagnostic devices consideration must be given to the compatibility of the materials used in the flexible circuit with the intended use of the device. For example, copper is incompatible with many electrochemical diagnostic applications, because it interferes with the measurements and can poison reactions. Copper is also incompatible with bio-medical substances and in-vivo uses. Accordingly, extra care and expense is often required in the design and manufacture of copper-based flexible circuits for medical diagnostic applications, including the specification of non-corrosive metal coverplates and conforming polymer covercoats, to ensure copper is not exposed in areas that would affect the diagnostic measurement functionality.

### SUMMARY OF INVENTION

The present invention features a novel copperless two-sided circuit and methods for making such a circuit.

One aspect of the invention provides an article including a two-sided circuit comprising a flexible polymeric substrate having two opposing surfaces and copperless metal traces or features on each substrate surface. The polymeric substrate may be a semi-crystalline polymer having a quasi-amorphous surface. The metal circuit may include a noble metal, which may be gold. The metal on both substrate surfaces may be the same or different. The two-sided circuit has many uses. For example, it may form part of a biosensor, such as a glucose sensor. It may also form a portion of a hard disk drive. The substrate thickness may be greater than the minimum distance between two traces on opposite surfaces of the substrate. Alternatively, the substrate thickness may be less than the minimum distance between two traces on a first surface of the substrate and a ground plane may be on a second opposing substrate surface.

Another aspect of the invention provides a method including: Providing a flexible polymeric substrate having two opposing surfaces and forming copperless metal traces or features on each substrate surface. polymeric substrate may be treated with rapid, pulsed high intensity ultra-violet light before the copperless metal traces are formed. The metal traces or features may be formed by: applying a copperless metal to opposing sides of a flexible polymeric substrate, forming a photoresist mask in the desired circuit pattern; removing the exposed portions of the metal layers; removing the photoresist mask to expose the desired circuit pattern; and plating the patterned metal layers. Alternatively, the metal traces may be formed by: applying a copperless metal to opposing sides of a flexible polymeric substrate, forming a photoresist mask in the negative image of the desired circuit pattern; plating the exposed portions of the metal layers; removing the photoresist mask; and etching the copperless metal until the exposed portion is removed from the substrate. Another alternative to forming the metal traces includes: applying a copperless metal to opposing sides of a flexible polymeric substrate, forming a photoresist mask in the image of the desired circuit pattern; etching the exposed copperless metal until it is removed from the substrate; and removing the photoresist mask. Subsequently, a covercoat layer may be applied over at least a portion of the metal layer; and the covercoat layer may be patterned to expose at least a portion of the metal layer.

An advantage of at least one embodiment of the present invention is that the two-sided construction allows the overall size of a circuit to be reduced as compared to a single sided circuit.

Another advantage of at least one embodiment of the present invention is that the trace density can be up to two times that of a single-sided circuit of the same relative size.

Another advantage of at least one embodiment of the present invention is eliminating copper from the construction provides cost benefits as well as opportunities for applications where copper cannot be used, such as medical applications.

Another advantage of at least one embodiment of the present invention is that a ground plane layer can be made to minimize cross-talk between traces.

Other features and advantages of the invention will be apparent from the following drawings, detailed description, and claims.

### BRIEF DESCRIPTION OF DRAWINGS

FIG. 1 depicts a subtractive process flow for making a circuit of the present invention.

FIG. 2 depicts a semi-additive process flow for making a circuit of the present invention.

FIG. 3 depicts a subtractive-additive process flow for making a circuit of the present invention.

### DETAILED DESCRIPTION

The circuit industry as a whole is moving to finer pitch circuitry and ultimately a smaller circuit. The minimum pitch that can successfully be processed limits the overall size of a single-sided circuit. In the hard disk drive industry, for example, the circuits have become sufficiently small that crosstalk between two adjacent traces becomes an issue. One solution is to add a ground plane feature on the opposite side of the circuit features, whereby the ground plane will minimize the amount of crosstalk between two traces. In the medical industry, biosensors are also approaching the physical limit in terms of size. One example is a system to continuously monitor a person's glucose levels, which includes a circuit inserted into the body's interstitial fluid. The circuit is part of an electrochemical cell that monitors glucose levels. Smaller circuits equate to a smaller needle size used for implantation, which means easier insertion and less pain.

Copper is a typical metal used in a circuit. It is subject to corrosion, so it is typical to gold-plate copper features where corrosion is an issue. More gold is used in gold plating a copper circuit than is used in making a copper-free, all gold trace. By substituting an all-gold trace for a copper/gold trace, not only is a process step eliminated (gold plating), but a cost reduction is possible due to lower gold usage. Also, copper may be harmful when in contact with internal body fluids. The elimination of copper entirely from the traces is advantageous, regardless of how the gold is applied, due to process step reduction and/or elimination of a potentially hazardous material.

Embodiment of the present invention may include a 2-sided copper-free circuit formed by various additive or subtractive processes, or a combination of the two, such as subtractively removing sputtered metal and additive plating. The circuit may optionally include a suitable tie-layer under the metal layer. The substrate is typically a dielectric or plastic material such as polyimide, polyester, polycarbonate, etc. The circuit may optionally have a covercoat. The circuit may have metal features (e.g. pads, electrodes, etc.) at one end of the circuit used to transmit information along circuit traces to another set of metal features that act as connector pads for some additional system, such as a monitor or circuit board.

A 2-sided copper-free trace circuit of the present invention has several unique advantages over standard copper/gold plated circuits. By placing circuit/metal features on both sides, the overall size of the circuit can be significantly reduced as compared to a single sided circuit. For example, if a standard circuit has two traces 32.5 μm wide separated by a 32.5 μm space (65 μm pitch), the smallest overall width the circuit could be is 97.5 μm plus the tolerance for cutting or punching (for chemical milling 50 μm on either side of the outside metal feature would be typical). Accordingly, 200 μm may be the approximate minimum width for a two-trace circuit. If instead the traces were on opposing sides of the substrate, the minimum size would be reduced to the trace width plus the punching or chemical milling tolerance (a reduction of 65 μm).

There may be additional advantages in separating the traces by the substrate in terms of crosstalk. For example, a 50.8 μm substrate is thicker than the minimum space distance between two traces that can be processed (about 32.5 μm). Thicker substrates would further increase the distance between two opposing traces (i.e., traces on opposite sides of the substrate). In theory, crosstalk between the opposing traces would become a non-issue. A further advantage is to use a ground plane on the substrate surface opposite the substrate surface having traces. For example, a 25.4 μm substrate is thinner than the minimum space distance between two traces that can be processed (about 32.5 em). A ground plane or other metal feature on the opposite side would be closer than this distance. Thus, crosstalk between the same side traces would be minimized.

The substrate of the present invention is a flexible polymer layer. Suitable substrates for the present invention are those that can be metallized. In various embodiments, it is preferable for the substrate material to be one or more of inert, heat stable, highly dielectric, and low cost. Various types of substrates can be used depending on the end user needs. If chemical milling is required, then polyimide or polycarbonate might be preferred. If no chemical milling is required, then polyester may be an appropriate choice due to its low cost. Suitable substrate materials for the present invention include, but are not limited to, polyimide, polyester, polyvinyl chloride, acrylate, polyolefin, polyester terephthalate, polyethylene naphthalate, polycarbonate, and liquid crystal polymers. Suitable thicknesses for the substrate will depend on the intended use, but are typically about 10 μm to about 600 μm.

If the substrate material is a semi-crystalline polymer it can optionally be surface-treated with a rapid thermal treatment with high intensity pulsed ultra-violet (UV) light, for example from a flashlamp or laser treatment, to improve its adhesion to metal layers. This type of treatment of semi-crystalline polymers is explained in detail in U.S. Pat. Nos. 4,822,451 and 4,879,176, which are incorporated herein in their entirety. The treatment causes the surface of the semi-crystalline polymer to become quasi-amorphous, which improves adhesion of the polymer to metal. Other suitable surface treatments include plasma treatments.

After the surface treatment, or instead of the surface treatment, an optional tie layer may be applied to the substrate to further enhance adhesion of the metal trace layer. Suitable tie layer metals include chrome, nickel-chrome, or other suitable metals. The tie layer may be deposited by plating, sputtering, evaporation deposition, using an adhesive, or other suitable means. The tie layer could also be an adhesive or organic material.

Suitable metals for the trace layers of the present invention include any non-corrosive metal, such as tin. Particularly suitable are noble metals, including, but not limited to, gold, silver, platinum, palladium and alloys thereof. The metal on opposing surfaces of the substrate may be the same or different. The metal layer may be deposited by plating, sputtering, evaporation deposition, using an adhesive, or other suitable means.

The two-sided flexible circuits of the present invention may be made having no polyimide features such as vias or slots, or having vias or slots in the circuits on one or both sides of the substrate. Vias or slots (i.e., polyimide features) are typically added when alignment or registration holes are needed, or a conductive path through the substrate is needed to connect the metal layers, to provide access to a metal feature from the opposite side, or to outline a circuit for singulation. Metallized polyimide features can be made by etching, punching, or laser drilling through the dielectric substrate and metallizing the opening.

The suitable thickness of a trace is determined by the required current carrying capacity, or inversely by the required resistance. In the types of processes described in detail below, subtractive, subtractive-additive, and semi-additive, trace thickness can be made on the nanometer level with a subtractive process or several microns with the semi-additive and subtractive-additive processes.

For a circuit used in a hard disk drive, the circuit is part of the assembly that connects the read/write head to the drive electronics. Examples of such circuits are illustrated in U.S. Pat. Nos. 5,924,187; 6,381,100; and 5,598,307.

For a circuit used as a biosensor, such as continuous measurement of glucose, the circuit is part of a system that is inserted into the body using some type of needle or half metal tube. An exemplary system for continuously monitoring glucose is disclosed in U.S. Pat. Nos. 6,248,067 and 6,809,653. Currently, circuits used for continuous glucose monitoring are single sided and seem to have reached the minimum size in terms of circuit width with current processing technology. The smaller size of a 2-sided circuit will allow for the needle size to be reduced, which in turn means less pain upon insertion. In the case of a biosensor implanted into the body, copper cannot be used for the metal features because it can react with bodily fluids. Gold is non-toxic with respect to bodily fluids and can be used for an implantable circuit.

To create a biosensor, a bioactive reagent (e.g. enzymes, antibody specific substances, antigens) would be placed on a transmit end gold circuit feature. The features may have a defined shape, size, and area depending on the requirements. These features may require an additional plating step of another metal like silver/silver chloride or platinum. When in contact with bodily fluid, such as interstitial fluids, an electrochemical cell is created that transmits current along the traces. The connector pads at the end of the traces are in contact with a monitor, by either a tethered cable or some other electrical connection, which receives and analyzes the transmitted information.

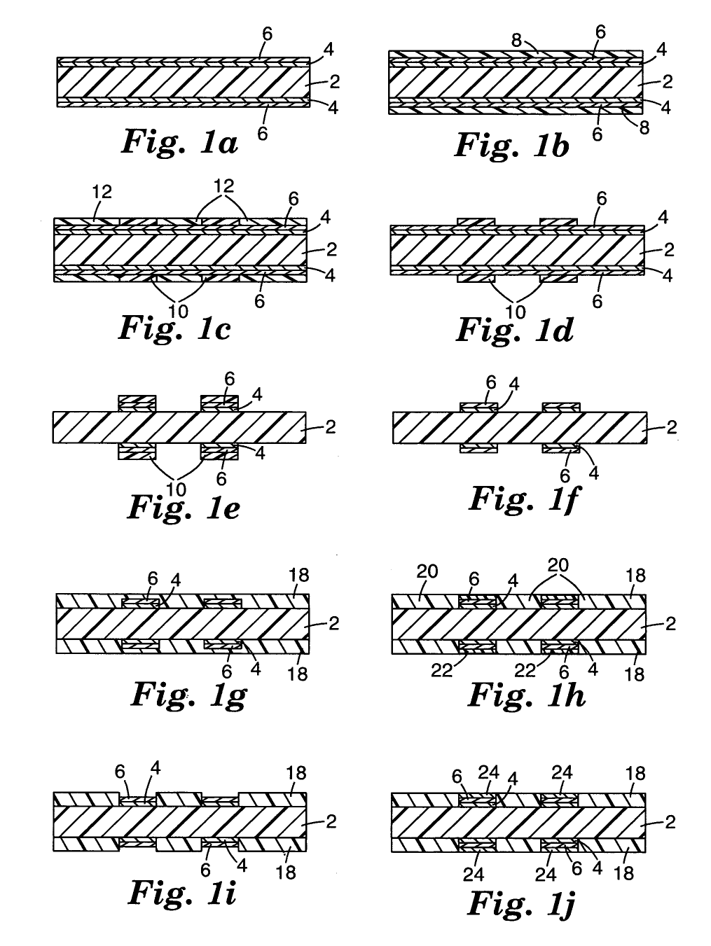

In a suitable subtractive process, a dielectric substrate 2 is first provided, as illustrated in FIG. 1a. The dielectric substrate may be a polymer film made of, for example, polyester, polyimide, liquid crystal polymer, polyvinyl chloride, acrylate, polycarbonate, or polyolefin having a thickness of about 10 μm to about 600 μm. The dielectric substrate has an optional tie layer 4 of chrome, nickel-chrome or other conductive metal deposited onto both sides, followed by deposition of the primary conductive layer 6 (e.g. gold (Au), Palladium (Pd), Platinum (Pt), Silver (Ag), Tin (Sn) and alloys thereof). Typically, a tie layer and metal layer are applied to one side of a continuous substrate, the continuous substrate is rewound and a tie layer and metal layer are applied to the other side of the substrate. Alternatively, the conductive metal layer may be formed directly on the dielectric substrate without the use of a tie layer, or with a tie layer on one side and without a tie layer on the opposite side. Optionally, the deposited conductive metal layer(s) can be plated up further to a desired thickness by known electroplating or electroless plating processes. Also, the conductive metal layers can be patterned by a number of well known methods including photolithography, print and etch, laser ablation and laser scribing.

As shown in FIG. 1b, an aqueous or solvent-processable photoresist 8, either negative or positive, is then laminated or coated onto at least one side of this substrate using standard laminating or coating techniques. The photoresist is then exposed on at least one side to ultraviolet light or the like, through a mask or phototool. For a negative photoresist, as shown in FIG. 1c, the exposed portions 10 are crosslinked and the unexposed portions 12 of the photoresist are then developed with the appropriate solvent to provide the structure shown in FIG. 1d. In the case of aqueous resists a dilute aqueous solution, e.g. a 0.5%-1.5% sodium or potassium carbonate solution, is applied until desired patterns are obtained.

As shown in FIG. 1e, the exposed portions of metal layer 6 are etched away using aqua regia, a mixture of HCl and HNO₃; triiodide-based etchant for Au (available from Transene Company Inc. (Danvers, Mass.), as GE-8148 etchant or GE-8111 etchant); thiourea (CH₄N₂S); ferro/ferricyanide etchants; or other suitable etchant. Then the exposed portions of the tie layer 4 are etched away using a potassium permanganate etchant, or other suitable etchant. The remaining (unexposed) conductive metal layer preferably has a final thickness from about 5 nm to about 200 μm. As shown in FIG. 1f, the crosslinked resist 10 is then stripped off both sides of the laminate in a 2-5% solution of an alkaline metal hydroxide at from about 20° C. to about 80° C., preferably from about 20° C. to about 60° C.

If desired the dielectric film may be etched to form features in the substrate by applying, crosslinking, and developing a pattern of photoresist, then placing the circuit into a bath of concentrated base at a temperature of from about 50° C. to about 120° C., preferably from about 50° C. to about 95° C., which etches the portions of the dielectric substrate not covered by the crosslinked resist. This exposes certain areas of the original thin conductive metal layer or creates a clean through hole. The resist is then stripped off the circuit in a 2-5% solution of an alkaline metal hydroxide from about 20° C. to about 80° C., preferably from about 20° C. to about 60° C.

As shown in FIG. 1g, the next step in the process, if desired, involves placing a photoimageable or screen printable covercoat 18 onto at least one side of the circuit. Examples of photoimageable covercoats are available under the trade name R/FLEX 8080 LIQUID PHOTOIMAGEABLE COVERCOAT from Rogers Corporation (Chandler, Ariz.) and flexible, photoimageable dry films available under the trade name PYRALUX PC from DuPont (Wilmington, Del.). The covercoat can be applied to one or both surfaces, either in a single step or two separate steps, using standard coating or laminating techniques. As shown in FIG. 1h, which shows liquid or dry film covercoat, the covercoat is then exposed on at least one side to ultraviolet light or the like, through a mask or phototool, crosslinking the exposed portions 20 of the covercoat. The unexposed portions 22 of the covercoat are then developed with the appropriate solvent, in the case of aqueous covercoats a dilute aqueous solution, e.g., a 0.5%-1.5% sodium or potassium carbonate solution, is applied until desired patterns are obtained, as shown in FIG. 1i. A final cure may be needed to sufficiently crosslink the remaining covercoat. The covercoat can be used to create selective plating areas, seal the circuit, or define an exposed area by creating an opening or edge boundary. The covercoat can also act as a corrosion inhibitor, isolate traces from one another, provide thermal protection, and provide electrical isolation.

As shown in FIG. 1j, if desired, the circuits can then be plated with metal 24 and/or singulated, packaged as needed for shipment and sale, or they can be packaged and shipped in web or panel form. Depending on the circuit design, the circuit layout and the requirements, it may be desirable to do converting and auditing steps prior to singulation where a sheet of circuits is converted to a smaller format. Other incidental steps may also be included in the process including soaking the film in hot water before or after the etching bath, rinsing steps and the like. Acid baths may also be used as a post-etching neutralization, and web-cleaning steps may follow plating steps.

Another possible method of forming the circuit portion would utilize semi-additive plating and the following typical step sequence:

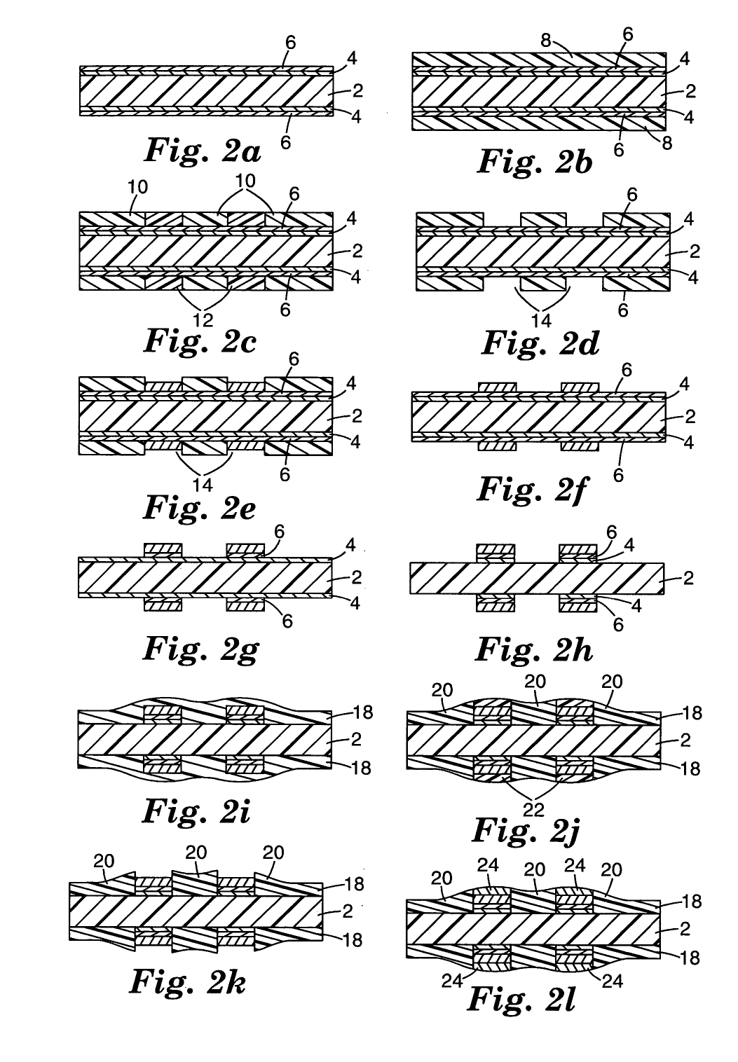

As shown in FIG. 2a, a dielectric substrate 2 may be coated with a tie layer 4 of chrome, nickel-chrome or alloys thereof using a vacuum sputtering or evaporation technique. A thin first conductive layer 6 of, e.g., gold, platinum, palladium or alloys thereof is deposited using a vacuum sputtering or evaporation technique. The materials and thicknesses for the dielectric substrate and conductive metal layer may be as described in the previous paragraphs.

The conductive metal layer can be patterned by a number of well known methods including photolithography, print and etch, laser ablation and laser scribing.

As shown in FIG. 2b, if photolithography is used, photoresists 8, which may be aqueous or solvent based, and may be negative or positive photoresists, are then laminated or coated on at least one side of the metal-coated dielectric substrate using standard laminating techniques with hot rollers or any number of coating techniques (e.g. knife coating, die coating, gravure roll coating, etc.). The thickness of the photoresist is from about 1 μm to about 50 μm. As shown in FIG. 2c, the photoresist is then exposed on at least one side to ultraviolet light or the like, through a mask or phototool, crosslinking the exposed portions 10 of the resist. As shown in FIG. 2d, the unexposed portions 12 of the photoresist are then developed with the appropriate solvent, in the case of aqueous resists a dilute aqueous solution, e.g., a 0.5%-1.5% sodium or potassium carbonate solution, is applied until desired patterns are obtained. The first exposed portions 14 of the conductive metal layer(s) may then be further plated, as shown in FIG. 2e, using standard electroplating or electroless plating methods until the desired circuit thickness in the range of about 5 nm to about 50 μm is achieved.

The cross-linked exposed portions of the resist 10 are then stripped off both sides of the laminate in a 2-5% solution of an alkaline metal hydroxide at from about 20° C. to about 80° C., preferably from about 20° C. to about 60° C. Subsequently, the original thin first conductive layer(s) 6 is/are etched where exposed, as shown in FIG. 2f, with an etchant that does not harm the dielectric substrate, e.g., a triiodide based etchant for gold (available from Transene Company Inc., (Danvers, Mass.), under the trade name GE-8148 or GE-8111); thiourea; or ferro/ferricyanide etchants. As shown in FIG. 2g, if the tie layer 4 is to be removed where exposed, it can be removed with appropriate etchants to provide the structure shown in FIG. 2h. If the tie layer is a thin metal, an insulator, or an organic material, it may be desirable to not remove the tie layer.

If desired the dielectric film may be etched to form features in the substrate by applying, crosslinking, and developing a pattern of photoresist, then placing the circuit into a bath of concentrated base at a temperature of from about 50° C. to about 120° C., preferably from about 50° C. to about 95° C., which etches the portions of the dielectric substrate not covered by the crosslinked resist. Etching all the way through the dielectric film can expose areas of the original thin conductive metal layer applied to the surface of the substrate opposite from the side on which the etching is initiated, or can create a clean through hole if the original metal layer was etched away at the location where the substrate layer is etched through. The photoresists are then stripped as described in the previous paragraphs.

As shown in FIG. 2i, the next step in the process, if desired, involves placing a photoimageable or screen printable covercoat 18 onto at least one side of the circuit. Examples of photoimageable covercoats are available under the trade name R/FLEX 8080 LIQUID PHOTOIMAGEABLE COVERCOAT from Rogers Corporation (Chandler, Ariz.) and flexible, photoimageable dry films available under the trade name PYRALUX PC from DuPont (Wilmington, Del.). The covercoat can be applied to one or both surfaces, either in a single step or two separate steps, using standard coating or laminating techniques. As shown in FIG. 2j, the covercoat 18 is then exposed on at least one side to ultraviolet light or the like, through a mask or phototool, crosslinking the exposed portions 20 of the covercoat. As shown in FIG. 2k, the unexposed portions 22 of the covercoat are then developed with the appropriate solvent, in the case of aqueous covercoats a dilute aqueous solution, e.g., a 0.5%-1.5% sodium or potassium carbonate solution, is applied until desired patterns are obtained. A final cure may be needed to sufficiently crosslink the remaining covercoat.

If desired, as shown in FIG. 21, the circuits can then be plated with metal 24, and/or singulated, packaged as needed for shipment and sale, or they can be packaged and shipped in web or panel form. Depending on the circuit design, the circuit layout and the requirements, it may be necessary to do converting and auditing steps prior to singulation where a sheet of circuits is converted to a smaller format. Other incidental steps may also be included in the process including soaking the film in hot water before or after the etching bath, rinsing steps and the like. Acid baths may also be used as a post-etching neutralization, and web-cleaning steps may follow plating steps.

Another possible method of forming the circuit portion would utilize a combination of subtractive and additive plating, referred to as a subtractive-additive method, and the following typical step sequence:

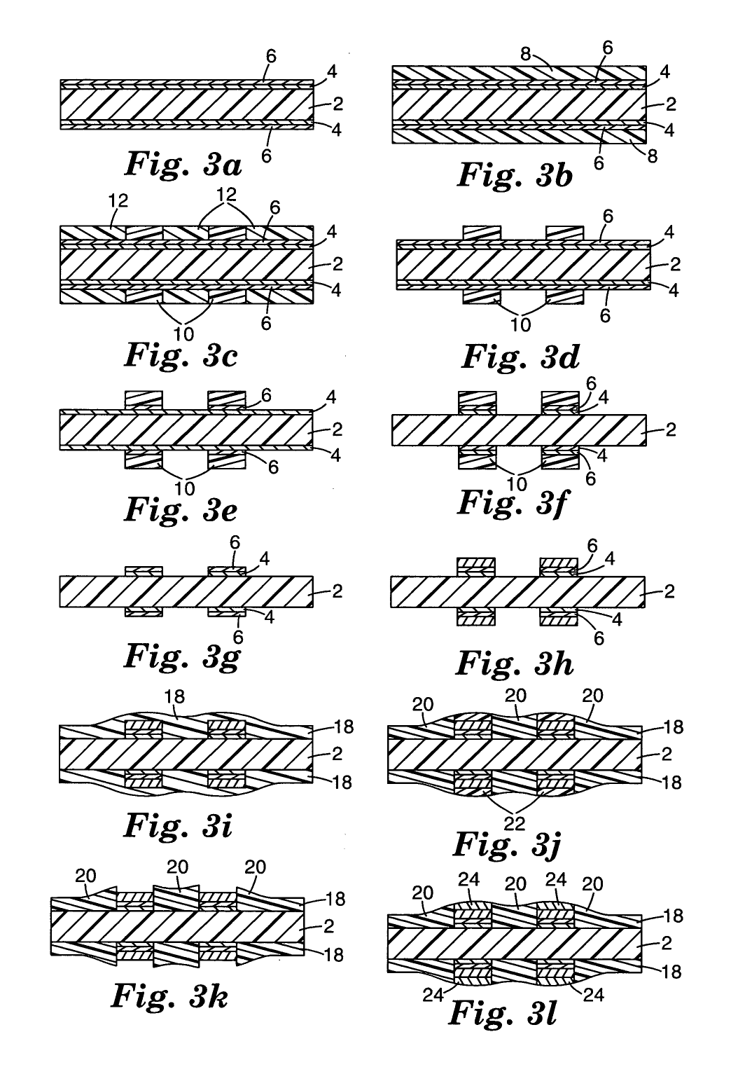

As shown in FIG. 3a, a dielectric substrate 2 may be coated with a tie layer 4 of, e.g., chrome, nickel-chrome or alloys thereof using, e.g., a vacuum sputtering or evaporation technique. A thin first conductive layer 6, e.g., of gold, platinum, palladium or alloys thereof is deposited using a vacuum sputtering or evaporation technique. The materials and thicknesses for the dielectric substrate and conductive metal layer may be as described in the previous paragraphs.

The conductive metal layer can be patterned by a number of well known methods including photolithography, print and etch, laser ablation and laser scribing.

As shown in FIG. 3b, if photolithography is used, an aqueous or solvent processable photoresist 8, either negative or positive, is laminated or coated onto at least one side of this substrate using standard laminating or coating techniques. The photoresist 8 is then exposed on at least one side to ultraviolet light or the like, through a mask or phototool. For a negative photoresist, the exposed portions 10 are crosslinked and the unexposed portions 12 of the photoresist are then developed with the appropriate solvent, as shown in FIG. 3c. In the case of aqueous resists a dilute aqueous solution, e.g. a 0.5%-1.5% sodium or potassium carbonate solution, is applied until desired patterns are obtained, as shown in FIG. 3d. As further shown in 3e, when the photoresist forms a positive pattern of the desired pattern for the metal layer 6, the exposed metal is etched away using aqua regia, triiodide-based etchant for Au (available from Transene Company Inc. (Danvers, Mass.), as GE-8148 or GE-8111); thiourea; ferro/ferricyanide etchants; or other suitable etchant. The tie layer 4 is then etched with a suitable etchant. The remaining (unexposed) conductive metal layer preferably has a final thickness from about 5 nm to about 200 μm. As shown in FIG. 3f, the exposed (crosslinked) portion 12 of the resist is then stripped off both sides of the laminate in a 2-5% solution of an alkaline metal hydroxide at from about 20° C. to about 80° C., preferably from about 20° C. to about 60° C., to provide the structure shown in FIG. 3g.

If desired the dielectric film may be etched to form features in the substrate by applying, crosslinking, and developing a pattern of photoresist, then placing the circuit into a bath of concentrated base at a temperature of from about 50° C. to about 120° C., preferably from about 50° C. to about 95° C., which etches the portions of the dielectric substrate not covered by the crosslinked resist. Etching all the way through the dielectric film can expose areas of the original thin conductive metal layer applied to the surface of the substrate opposite from the side on which the etching is initiated, or can create a clean through hole if the original metal layer was etched away at the location where the substrate layer is etched through. The resist is then stripped off the circuit in a 2-5% solution of an alkaline metal hydroxide from about 20° C. to about 80° C., preferably from about 20° C. to about 60° C.

As shown in FIG. 3h, the exposed portions of first conductive metal layer(s) 6 may then be further plated using standard electroplating or electroless plating methods until the desired circuit thickness in the range of about 5 nm to about 50 μm is achieved.

As shown in FIG. 3i, the next step in the process, if desired, involves placing a photoimageable or screen printable covercoat 18 onto at least one side of the circuit. Examples of photoimageable covercoats are those available under the trade name R/FLEX 8080 LIQUID PHOTOIMAGEABLE COVERCOAT from Rogers Corporation (Chandler, Ariz.) and flexible, photoimageable dry films available under the trade name PYRALUX PC from DuPont (Wilmington, Del.). The covercoat can be applied to one or both surfaces, either in a single step or two separate steps, using standard coating or laminating techniques. As shown in FIG. 3i, the covercoat 18 is then exposed on at least one side to ultraviolet light or the like, through a mask or phototool. As shown in FIG. 3j, the exposed portions 20 of the covercoat are crosslinked. The unexposed portions 22 of the covercoat are then developed with the appropriate solvent, in the case of aqueous covercoats a dilute aqueous solution, e.g., a 0.5%-1.5% sodium or potassium carbonate solution, is applied until desired patterns are obtained, as shown in FIG. 3k. A final cure may be needed to sufficiently crosslink the remaining covercoat.

As shown in FIG. 31, if desired, the circuits can then be plated with metal 24 and/or singulated, packaged as needed for shipment and sale, or they can be packaged and shipped in web or panel form. Depending on the circuit design, the circuit layout and the requirements, it may be necessary to do converting and auditing steps prior to singulation where a sheet of circuits is converted to a smaller format. Other incidental steps may also be included in the process including soaking the film in hot water before or after the etching bath, rinsing steps and the like. Acid baths may also be used as a post-etching neutralization, and web-cleaning steps may follow plating steps.

Various modifications and alterations of this invention will become apparent to those skilled in the art without departing from the scope and spirit of this invention and it should be understood that this invention is not to be unduly limited to the illustrative embodiments set forth herein.

What is claimed is:

1. An article comprising:
a two-sided circuit comprising a flexible polymeric substrate having two opposing surfaces and
copperless metal traces or features on each substrate surface.

2. The article of claim 1 wherein the polymeric substrate is a semi-crystalline polymer having a quasi-amorphous surface.

3. The article of claim 1 wherein the metal circuit comprises a noble metal.

4. The article of claim 3 wherein the noble metal is gold.

5. The article of claim 1 wherein the metal on both substrate surfaces is the same.

6. The article of claim 1 wherein the metal on each substrate surface is different.

7. The article of claim 1 wherein the two-sided circuit forms a portion of a biosensor.

8. The article of claim 7 wherein the biosensor is a glucose sensor.

9. The article of claim 1 wherein the two-sided circuit forms a portion of a hard disk drive.

10. The article of claim 1 wherein the substrate thickness is greater than the minimum distance between two traces on opposite surfaces of the substrate.

11. The article of claim 1 wherein the substrate thickness is less than the minimum distance between two traces on a first surface of the substrate and wherein a ground plane is on a second opposing substrate surface.

12. A method comprising:
providing a flexible polymeric substrate having two opposing surfaces, and forming copperless metal traces or features on each substrate surface.

13. The method of claim 12 wherein the polymeric substrate is treated with rapid, pulsed high intensity ultra-violet light before the copperless metal traces or features are formed.

14. The method of claim 12 wherein the formation of the metal traces or features comprises:
applying a copperless metal to opposing sides of a flexible polymeric substrate, forming a photoresist mask in the desired circuit pattern;
removing the exposed portions of the metal layers;
removing the photoresist mask to expose the desired circuit pattern; and
plating the patterned metal layers.

15. The method of claim 12 further comprising:
applying a covercoat layer over at least a portion of the metal layer; and
patterning the covercoat layer to expose at least a portion of the metal layer.

16. The method of claim 15 further comprising plating the exposed metal layer.

17. The method of claim 12 comprising:
applying a copperless metal to opposing sides of a flexible polymeric substrate, forming a photoresist mask in the negative image of the desired circuit pattern;
plating the exposed portions of the metal layers;
removing the photoresist mask; and
etching the copperless metal until the exposed portion is removed from the substrate.

18. The method of claim 17 further comprising:
applying a covercoat layer over at least a portion of the metal layer; and
patterning the covercoat layer to expose at least a portion of the metal layer.

19. The method of claim 18 further comprising plating the exposed metal layer.

20. The method of claim 12 comprising:
applying a copperless metal to opposing sides of a flexible polymeric substrate, forming a photoresist mask in the image of the desired circuit pattern;
etching the exposed copperless metal until it is removed from the substrate; and
removing the photoresist mask.

21. The method of claim 20 further comprising:
applying a covercoat layer over at least a portion of the metal layer; and
patterning the covercoat layer to expose at least a portion of the metal layer.

22. The method of claim 21 further comprising plating the exposed metal layer.
